(19) United States
(12) Patent Application Publication
(10) Pub. No.: US 2008/0318420 A1
(43) Pub. Date: Dec. 25, 2008

(54) TWO STEP CHEMICAL MECHANICAL POLISH

(76) Inventors: Denny K. Wong, Fremont, CA (US); Weechen Gan, Cupertino, CA (US); Xinyu Zhang, Palo Alto, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/766,922

(22) Filed: Jun. 22, 2007

(51) Int. Cl. H01L 21/4763

(52) U.S. Cl. 438/669; 257/E21.484

(57) ABSTRACT

In one embodiment, a method includes providing two structures with a spacing therebetween over a semiconductor substrate, providing a conformal first layer over the two structures and within the space therebetween, depositing a conformal protective layer over the first layer, planarizing the protective layer until a top surface of the first layer is exposed, and planarizing the first layer and the protective layer until a top surface of the two structures is exposed and a portion of the protective layer is between the two structures.

### BACKGROUND

1. Field of Invention

The present invention generally relates to semiconductor processing and, more particularly, to an advantageous method of chemical mechanical polish (CMP).

2. Related Art

With increasing densities of up to hundreds of thousands of devices on a single chip, planar surfaces formed to precise specification is desirable to avoid degradation of and inefficient device performance.

Chemical-mechanical planarization or polishing (CMP) has been a technique used in semiconductor fabrication for planarizing the top surface of a substrate during fabrication. CMP typically involves the use of an abrasive and corrosive chemical slurry in conjunction with a polishing pad and retaining ring to remove material in a planar and uniform fashion. However, conventional CMP has been applied in one step and the removal rate of material has been very dependent on pattern density, with higher density areas having a lower removal rate than lower density areas. As desired material is removed in the high density area, the lower density area with the higher removal rate may become over-polished, resulting in non-planar dishing effects on the surface. Such a dishing effect can adversely affect the topography and performance of the fabricated device. Therefore a method for CMP that avoids non-planar effects is highly desirable.

### SUMMARY

The present invention provides a method for two step CMP that advantageously avoids a dishing effect.

In one embodiment of the present invention, a method includes providing two structures with a spacing therebetween over a semiconductor substrate, providing a conformal first layer over the two structures and within the space therebetween, depositing a conformal protective layer over the first layer, planarizing the protective layer until a top surface of the first layer is exposed, and planarizing the first layer and the protective layer until a top surface of the two structures is exposed and a portion of the protective layer is between the two structures.

In another embodiment, a method includes providing a substrate, providing a low density pattern region over the substrate, the low density pattern region including at least two structures with a spacing greater than about 50 microns wide therebetween, and providing a high density pattern region over the substrate, the high density pattern region including at least two structures with a space less than about 0.2 micron therebetween. The method further includes providing a conformal first layer over the low density pattern region and the high density pattern region, depositing a conformal protective layer over the first layer, planarizing the protective layer until a top surface of the first layer is exposed, and planarizing the first layer and the protective layer until a top surface of the structures of the low density pattern region and the high density pattern region is exposed and a portion of the protective layer is between the at least two structures of the low density region.

The scope of the invention is defined by the claims, which are incorporated into this section by reference. A more complete understanding of embodiments of the present invention will be afforded to those skilled in the art, as well as a realization of additional advantages thereof, by a consideration of the following detailed description of one or more embodiments. Reference will be made to the appended sheets of drawings that will first be described briefly.

### BRIEF DESCRIPTION OF DRAWINGS

FIG. 1 illustrates a cross-sectional view of a semiconductor substrate with a high density pattern region and a low density pattern region including a first active layer over the topography of the semiconductor substrate.

FIG. 2 illustrates a cross-sectional view of the structure illustrated in FIG. 1 after deposition of a protective layer.

FIG. 3 illustrates a cross-sectional view of the structure illustrated in FIG. 2 after a first CMP step.

FIG. 4 illustrates a cross-sectional view of the structure illustrated in FIG. 3 after a second CMP step.

Embodiments of the present invention and their advantages are best understood by referring to the detailed description that follows. It should be appreciated that like reference numerals are used to identify like elements illustrated in one or more of the figures. It should also be appreciated that the figures may not be necessarily drawn to scale.

### DETAILED DESCRIPTION

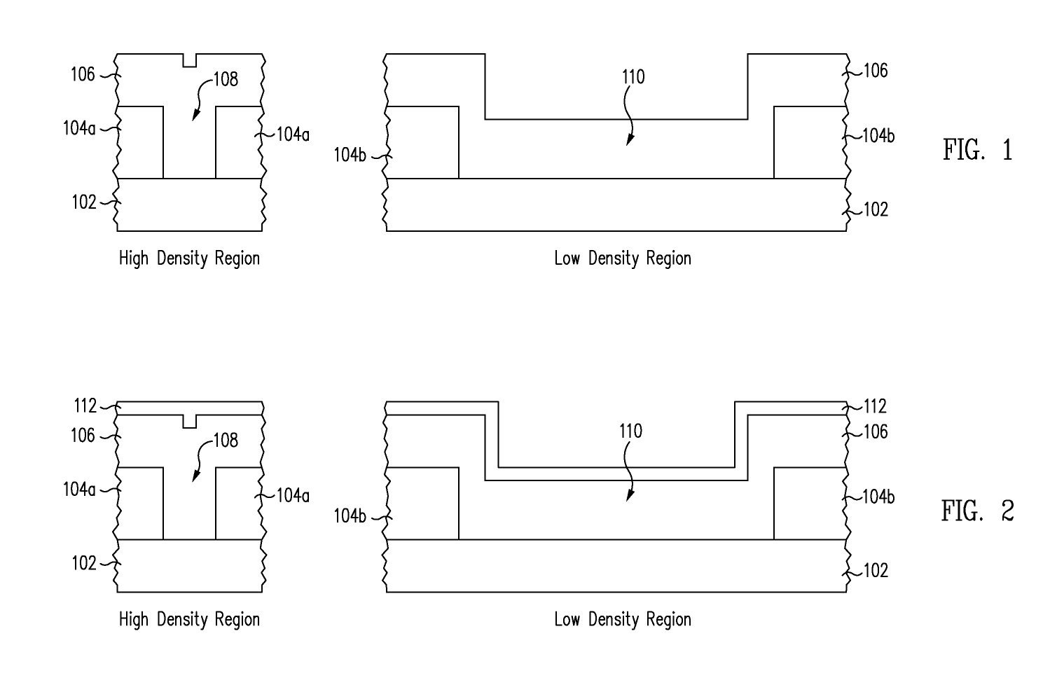

The present invention provides a method for two step chemical-mechanical planarization or polishing (CMP) that advantageously avoids dishing effects. FIGS. 1-4 illustrate cross-sectional views of one example of a semiconductor manufacturing process in which the present invention may be used.

Referring to FIG. 1, a cross-sectional view of a semiconductor substrate 102 with a high density pattern region and a low density pattern region is illustrated. Substrate 102 may be a wafer formed from a single crystalline silicon material, but may also comprise other materials, for example, an epitaxial material, a polycrystalline semiconductor material, or other suitable material. Substrate 102 may be doped by conventional means with dopants at different dosage and energy levels. It is noted that substrate 102 can further include additional layers, structures, and/or devices.

Structures 104a and 104b with a spacing therebetween are formed over substrate 102. In one example, structures 104a have a spacing 108 therebetween in the high density region that is less than about 0.2 micron, and structures 104b have a spacing 110 therebetween in the low density region that is more than about 50 microns. In one example, structures 104a and 104b have substantially the same height in both the high and low density regions, with the height ranging between about 0.05 micron and about 0.5 micron. Structures 104a and 104b may be formed by photolithography and etch processes, and also by CMP and etching away unwanted film between the two structures. Other methods may also be used to form such structures.

It is noted that the high density region and the low density region may be juxtaposed next to one another or may be separated by various areas, regions, or circuitry of the substrate or device. In one example, the high density region may be a memory array region of a flash memory device and may include a plurality of gate structures, with each gate structure having a polysilicon layer and an insulator layer. In a further example, the low density region may be a periphery region of a flash memory device and may include support circuitry, such as read/write/erase control circuitry, a decoder, or other necessary controlling components.

A first active layer 106 is formed in a conformal manner over the topography of the semiconductor substrate. Active layer 106 may be comprised of various materials, including but not limited to amorphous silicon or polysilicon, tungsten, silicon oxide, aluminum, copper, and a dielectric. Active layer 106 may also be formed by various techniques, including but not limited to chemical vapor deposition (CVD), spin-on coating, and/or by other various means and methods.

Referring now to FIG. 2, a cross-sectional view of the structure illustrated in FIG. 1 after conformal deposition of a protective layer 112 is shown. In one example, protective layer 112 is deposited to a thickness less than about 0.05 micron. Protective layer 112 may be comprised of various materials including but not limited to silicon dioxide, silicon nitride, oxynitride, TiW, silicon, tantalum oxide, and PVD metals. Protective layer 112 may also be formed by various techniques, including but not limited to CVD and physical vapor deposition (PVD).

Table 1 below lists examples of particular protective layers that may be advantageously used in conjunction with particular active layers.

TABLE 1

| ACTIVE LAYER | PROTECTIVE LAYER |
|---|---|
| Amorphous Silicon or | Thermal or CVD silicon dioxide; |
| Polysilicon | silicon nitride; oxynitride |
| Tungsten | Oxynitride; silicon nitride; TiW; |
| | amorphous silicon; polysilicon |
| CVD Silicon Oxide | Silicon nitride; polysilicon |
| Aluminum | CVD silicon dioxide; silicon |
| | nitride; oxynitride |
| Copper | Tantalum oxide |
| Low-K Dielectric | PVD metals |

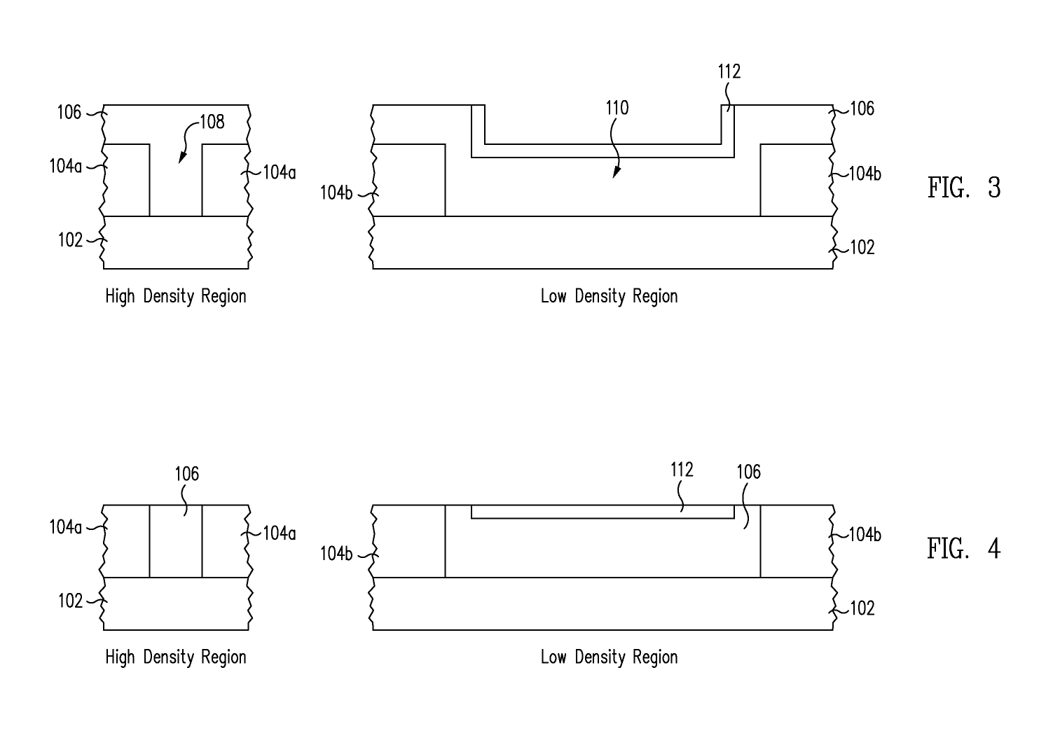

Referring now to FIG. 3, a cross-sectional view of the structure illustrated in FIG. 2 after a first CMP step is illustrated. The first CMP step may be applied with a high selectivity slurry between a top surface of passive layer 112 to active layer 106 in one example. The first CMP is applied until a top surface of active layer 106 is exposed in the high density region or of the low density region. Various endpoint methods may be used to end the first CMP step, including but not limited to a predetermined time, motor current, optical detection by shifting of temperature, reflectance, and so on.

Referring now to FIG. 4, a cross-sectional view of the structure illustrated in FIG. 3 after a second CMP step is illustrated. The second CMP step may be applied with a high selectivity slurry between a top surface of active layer 106 to passive layer 112 and underlying layer 104a and 104b in one example. The second CMP is applied until a top surface of structures 104a or 104b is exposed and a portion of protective layer 112 remains between structures 104b and above active layer 106. Thus, protective layer 112 advantageously prevents a dishing effect between structures 104b in the low density region. Various endpoint methods may be used to end the second CMP step, including but not limited to a predetermined time, motor current, optical detection by shifting of temperature, reflectance, and so on.

After the second CMP step (as shown in FIG. 4), the remaining portion of protective layer 112 may be left on or etched away. Protective layer 112 may be etched away by various methods, including but not limited to chemical etch dependent upon film type of protective layer 112 to layer 104a and 104b so as to provide a one to one or other high selectivity etch ratio.

It is noted that the configuring of a deposition tool and/or a CMP tool in response to pre-selected parameters, such as for layer thickness and/or endpoint detection, may be automated. A deposition tool and/or CMP tool or process in accordance with the present disclosure may therefore include the use of a computer to carry out the automatic settings of parameters to realize a computer-determined or otherwise specified CMP process to reduce dishing effects. A computer-readable medium or another form of a software product or machine-instructing means (including but not limited to, a hard disk, a compact disk, a flash memory stick, a downloading of manufactured instructing signals over a network and/or like software products) may be used for instructing an instructable machine (e.g., a CMP tool) to carry out such automated activities. As such, it is within the scope of the disclosure to have an instructable machine carry out, and/or to provide a software product adapted for causing an instructable CMPT tool to carry out the disclosed CMP process.

Advantageously, the present invention provides for a CMP method to reduce and control dishing effects while providing planar surfaces with good uniformity.

Embodiments described above illustrate but do not limit the invention. It should also be understood that numerous modifications and variations are possible in accordance with the principles of the present invention. For example, it is noted that the invention is not limited to the aforementioned example but can involve various layers and layer thicknesses depending upon desired applications of the present disclosure. Accordingly, the scope of the invention is defined only by the following claims.

What is claimed is:

1. A method comprising:
providing two structures with a spacing therebetween over a semiconductor substrate;
providing a conformal first layer over the two structures and within the space therebetween;
depositing a conformal protective layer over the first layer;
planarizing the protective layer until a top surface of the first layer is exposed; and
planarizing the first layer and the protective layer until a top surface of the two structures is exposed and a portion of the protective layer is between the two structures.

2. The method of claim 1, wherein the spacing is greater than about 50 microns wide and between about 0.05 micron and about 0.5 micron high.

3. The method of claim 1, wherein the first layer is comprised of a material selected from the group consisting of silicon, tungsten, silicon oxide, aluminum, copper, and a dielectric.

4. The method of claim 1, wherein the protective layer is comprised of a material selected from the group consisting of silicon dioxide, nitride, oxynitride, TiW, silicon, tantalum oxide, and PVD metals.

5. The method of claim 1, wherein the first layer is comprised of amorphous silicon or polysilicon, and the protective layer is comprised of silicon dioxide, silicon nitride, or oxynitride.

6. The method of claim 1, wherein the first layer is comprised of tungsten and the protective layer is comprised of oxynitride, silicon nitride, TiW, amorphous silicon, or polysilicon.

7. The method of claim 1, wherein the first layer is comprised of silicon oxide and the protective layer is comprised of nitride or polysilicon.

8. The method of claim 1, wherein the first layer is comprised of aluminum and the protective layer is comprised of silicon dioxide, silicon nitride, or oxynitride.

9. The method of claim 1, wherein the first layer is comprised of copper and the protective layer is comprised of tantalum oxide.

10. The method of claim 1, wherein the first layer is comprised of a low-k dielectric and the protective layer is comprised of a PVD metal.

11. The method of claim 1, wherein the protective layer is less than about 0.05 micron.

12. The method of claim 1, wherein the planarizing is performed by chemical mechanical planarization with a high selectivity slurry.

13. The method of claim 1, further comprising removing the portion of the protective layer using a chemical etchant.

14. A method comprising:
providing a substrate;
providing a low density pattern region over the substrate, the low density pattern region including at least two structures with a spacing greater than about 50 microns wide therebetween;
providing a high density pattern region over the substrate, the high density pattern region including at least two structures with a space less than about 0.2 micron therebetween;
providing a conformal first layer over the low density pattern region and the high density pattern region;
depositing a conformal protective layer over the first layer;
planarizing the protective layer until a top surface of the first layer is exposed; and
planarizing the first layer and the protective layer until a top surface of the structures of the low density pattern region and the high density pattern region is exposed and a portion of the protective layer is between the at least two structures of the low density pattern region.

15. The method of claim 14, wherein the first layer is comprised of a material selected from the group consisting of silicon, tungsten, silicon oxide, aluminum, copper, and a dielectric.

16. The method of claim 14, wherein the protective layer is comprised of a material selected from the group consisting of silicon dioxide, nitride, oxynitride, TiW, silicon, tantalum oxide, and PVD metals.

17. The method of claim 14, wherein the first layer is comprised of amorphous silicon or polysilicon, and the protective layer is comprised of silicon dioxide, silicon nitride, or oxynitride.

18. The method of claim 14, wherein the first layer is comprised of tungsten and the protective layer is comprised of oxynitride, silicon nitride, TiW, amorphous silicon, or polysilicon.

19. The method of claim 14, wherein the first layer is comprised of silicon oxide and the protective layer is comprised of nitride or polysilicon.

20. The method of claim 14, wherein the first layer is comprised of aluminum and the protective layer is comprised of silicon dioxide, silicon nitride, or oxynitride.

21. The method of claim 14, wherein the first layer is comprised of copper and the protective layer is comprised of tantalum oxide.

22. The method of claim 14, wherein the first layer is comprised of a low-k dielectric and the protective layer is comprised of a PVD metal.

23. The method of claim 14, wherein the planarizing is performed by chemical mechanical planarization with a high selectivity slurry.
